(19) United States
(12) Patent Application Publication
(10) Pub. No.: US 2026/0005184 A1
(43) Pub. Date: Jan. 1, 2026

(54) SEMICONDUCTOR DEVICE

(71) Applicant: Kioxia Corporation, Tokyo (JP)

(72) Inventor: Yusuke AKADA, Yokohama (JP)

(73) Assignee: Kioxia Corporation, Tokyo (JP)

(21) Appl. No.: 19/074,693

(22) Filed: Mar. 10, 2025

(30) Foreign Application Priority Data
Jun. 28, 2024 (JP) 2024-105226

(51) Int. Cl. H01L 23/00; H01L 23/31; H01L 23/538; H01L 25/07

(52) U.S. Cl. CPC H01L 24/48; H01L 23/5386; H01L 24/49; H01L 25/074; H01L 23/3107; H01L 2224/48145; H01L 2224/48249; H01L 2224/48491; H01L 2224/49112; H01L 2224/49171; H01L 2225/06506; H01L 2225/0651; H01L 2225/06562

(57) ABSTRACT

A semiconductor device includes: a wiring substrate including a first bonding pad and a second bonding pad aligned with the first bonding pad in a first direction; a semiconductor element provided on the wiring substrate; and a connection wiring connecting the first bonding pad to the semiconductor element and including a first bonding wire and a second bonding wire arranged in the first direction. The first bonding pad includes a region not connected to the connection wiring, the region being partitioned by a protrusion provided on a surface of the first bonding pad, and being partitioned in a non-perpendicular direction with respect to the first direction or physically partially partitioned.

### CROSS-REFERENCE TO RELATED APPLICATION

This application is based upon and claims the benefit of priority from Japanese Patent Application No. 2024-105226, filed Jun. 28, 2024, the entire contents of which are incorporated herein by reference.

### FIELD

Embodiments described herein relate generally to a semiconductor device.

### BACKGROUND

In semiconductor packages, semiconductor elements provided on wiring substrates are connected by bonding wires. For example, to enhance a power system, a plurality of bonding wires may be connected from one bonding pad to different bonding pads of the semiconductor element.

### DESCRIPTION OF THE DRAWINGS

FIG. 1 is a schematic view illustrating a semiconductor device according to an embodiment;

FIG. 2 is a schematic sectional view illustrating the semiconductor device according to the embodiment;

FIG. 3 is a schematic view illustrating vicinity of a first bonding pad of the semiconductor device according to the embodiment;

FIG. 4 is a schematic view illustrating a first bonding pad of a semiconductor device as a reference.

FIG. 5 is a schematic view illustrating the first bonding pad of the semiconductor device according to the embodiment;

FIG. 6 is a schematic view illustrating the first bonding pad of the semiconductor device according to the embodiment;

FIG. 7 is a schematic view illustrating the first bonding pad of the semiconductor device according to the embodiment;

FIG. 8 is a schematic view illustrating the first bonding pad of the semiconductor device according to the embodiment;

FIG. 9 is a schematic view illustrating the first bonding pad of the semiconductor device according to the embodiment;

FIG. 10 is a schematic view illustrating the first bonding pad of the semiconductor device according to the embodiment;

FIG. 11 is a schematic view illustrating the first bonding pad of the semiconductor device according to the embodiment;

FIG. 12 is a schematic view illustrating the first bonding pad of the semiconductor device according to the embodiment;

FIG. 13 is a schematic view illustrating the first bonding pad of the semiconductor device according to the embodiment;

FIG. 14 is a schematic view illustrating a semiconductor device according to an embodiment;

FIG. 15 is a schematic sectional view illustrating the semiconductor device according to the embodiment; and

FIG. 16 is a flowchart illustrating a method of manufacturing the semiconductor device according to the embodiment.

### DETAILED DESCRIPTION

Embodiments provide a semiconductor device in which durability or reliability is improved.

In general, according to one embodiment, a semiconductor device includes: a wiring substrate including a first bonding pad and a second bonding pad aligned with the first bonding pad in a first direction; a semiconductor element provided on the wiring substrate; and a connection wiring connecting the first bonding pad to the semiconductor element and including a first bonding wire and a second bonding wire arranged in the first direction. The first bonding pad includes a region not connected to the connection wiring, the region being partitioned by a protrusion provided on a surface of the first bonding pad, and being partitioned in a non-perpendicular direction with respect to the first direction or physically partially partitioned.

Hereinafter, embodiments will be described with reference to the drawings.

In the present specification, a plurality of exemplary expressions are given to several elements. The exemplary expressions are merely illustrative and do not preclude the elements from being expressed differently. Elements without a plurality of expressions may also be expressed differently.

The drawings are schematic and relationships between thicknesses and planar dimensions, ratios of thicknesses of layers, and the like may differ from reality. There are portions in which relationships between dimensions and ratios are different depending on the drawings. In the drawings, some reference signs are omitted.

### First Embodiment

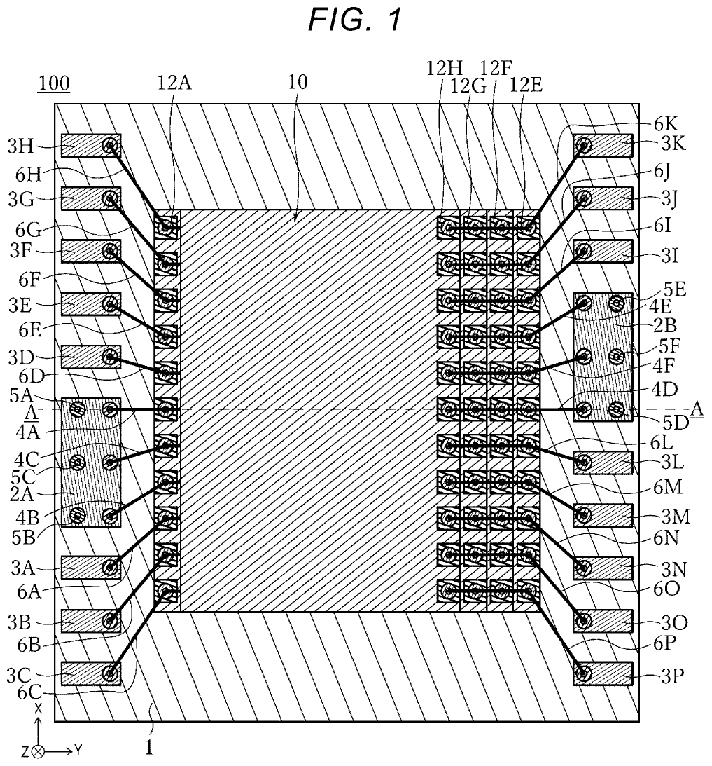

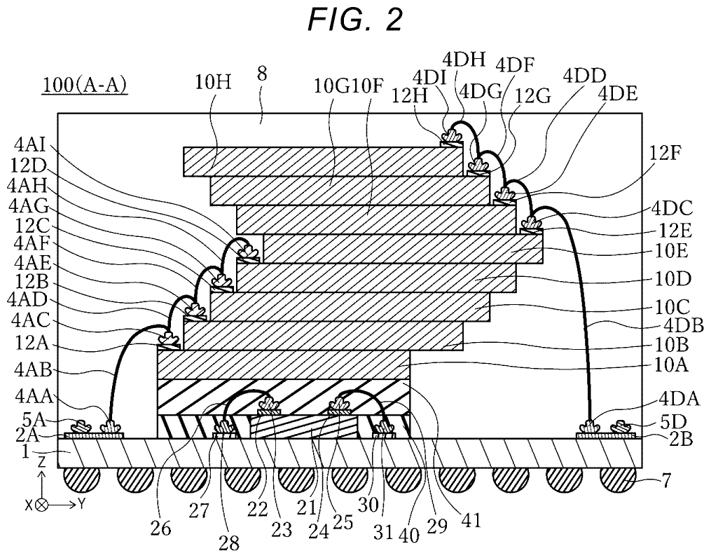

A first embodiment relates to a semiconductor device. FIG. 1 is a schematic view illustrating a semiconductor device 100. FIG. 2 is an A-A sectional view of the semiconductor device 100. The semiconductor device 100 according to the embodiment is a semiconductor package on which a semiconductor element including one or more types selected from a group consisting of an arithmetic device, a control device, and a storage device. Preferably, an X direction, a Y direction, and a Z direction intersect each other and are orthogonal to each other.

The semiconductor device 100 includes a wiring substrate 1, solder balls 7, an encapsulant 8, a first semiconductor element 10, a second semiconductor element 21, a first insulating layer 40, and a second insulating layer 41.

The wiring substrate 1 is a supporting substrate of the first semiconductor element 10 and the second semiconductor element 21. More specifically, the wiring substrate 1 is a multilayered wiring substrate. The first semiconductor element 10 and the second semiconductor element 21 are provided on a first surface side of the wiring substrate 1. On a second surface side facing the first surface of the wiring substrate 1, hemisphere electrodes such as the solder balls 7 for connection with the outside of the semiconductor device 100 are provided.

The wiring substrate 1 is electrically connected to the first semiconductor element 10 and the second semiconductor element 21 via bonding wires. The wiring substrate 1 includes, for example, a terminal such as a first bonding pad 2A connected to the first semiconductor element 10. The terminal includes a power terminal including a terminal for grounding and a signal terminal for IO, and each terminal is provided on the wiring substrate 1. For example, the signal terminal is a terminal for input and output of data with respect to the first semiconductor element 10 or a terminal for inputting a control signal by which an operation of the first semiconductor element 10 is controlled.

The wiring substrate 1 illustrated in the schematic view of FIG. 1 includes the first bonding pad 2A, a second bonding pad 3A, a fourth bonding pad 3B, a fifth bonding pad 3C, a sixth bonding pad 3D, a seventh bonding pad 3E, an eighth bonding pad 3F, a ninth bonding pad 3G, a tenth bonding pad 3H, an eleventh bonding pad 2B, a twelfth bonding pad 3I, a thirteenth bonding pad 3J, a fourteenth bonding pad 3K, a fifteenth bonding pad 3L, a sixteenth bonding pad 3M, a seventeenth bonding pad 3N, an eighteenth bonding pad 3O, and a nineteenth bonding pad 3P.

The first semiconductor element 10 includes, for example, a first semiconductor chip 10A, a second semiconductor chip 10B, a third semiconductor chip 10C, a fourth semiconductor chip 10D, a fifth semiconductor chip 10E, a sixth semiconductor chip 10F, a seventh semiconductor chip 10G, and an eighth semiconductor chip 10H. The first semiconductor chip 10A, the second semiconductor chip 10B, the third semiconductor chip 10C, the fourth semiconductor chip 10D, the fifth semiconductor chip 10E, the sixth semiconductor chip 10F, the seventh semiconductor chip 10G, and the eighth semiconductor chip 10H are stacked in this order in the Z direction.

Four semiconductor chips (the first semiconductor chip 10A, the second semiconductor chip 10B, the third semiconductor chip 10C, and the fourth semiconductor chip 10D) are stacked in the Z direction and displaced in the Y direction. Four semiconductor chips (the fifth semiconductor chip 10E, the sixth semiconductor chip 10F, the seventh semiconductor chip 10G, and the eighth semiconductor chip 10H) are disposed oriented to a direction in which other four semiconductor chips (the first semiconductor chip 10A, the second semiconductor chip 10B, the third semiconductor chip 10C, and the fourth semiconductor chip 10D) are rotated by 180°, and are stacked in the Z direction and displaced in an opposite direction to the Y direction.

The first semiconductor chip 10A, the second semiconductor chip 10B, the third semiconductor chip 10C, the fourth semiconductor chip 10D, the fifth semiconductor chip 10E, the sixth semiconductor chip 10F, the seventh semiconductor chip 10G, and the eighth semiconductor chip 10H are, for example, bare chips and respectively include a plurality of terminals 12A, a plurality of terminals 12B, a plurality of terminals 12C, a plurality of terminals 12D, a plurality of terminals 12E, a plurality of terminals 12F, a plurality of terminals 12G, and a plurality of terminals 12H.

The first semiconductor element 10 includes, for example, a plurality of semiconductor memory chips. The semiconductor memory chip is a semiconductor chip that reads and writes data. The semiconductor memory chip is a nonvolatile memory chip or a volatile memory chip. As the nonvolatile memory chip, a NAND memory chip, a phase-change memory chip, a resistive memory chip, a ferroelectric memory chip, a magnetic memory chip, or the like may be used. As the volatile memory chip, a dynamic random access memory (DRAM) or the like may be used. The semiconductor memory chips are preferably semiconductor chips that have the same circuits and the same structures except for individual differences. The first bonding pad 2A is a power terminal and is appropriate for a high-speed memory operation since power of the first semiconductor element 10 is enhanced when a plurality of bonding wires are provided from the first bonding pad 2A.

The first bonding pad 2A, the second bonding pad 3A, the fourth bonding pad 3B, the fifth bonding pad 3C, the sixth bonding pad 3D, the seventh bonding pad 3E, the eighth bonding pad 3F, the ninth bonding pad 3G, and the tenth bonding pad 3H are each connected to the plurality of terminals 12A of the first semiconductor chip 10A.

The first semiconductor chip 10A is connected to the second semiconductor chip 10B by connecting the plurality of terminals 12A of the first semiconductor chip 10A to the plurality of terminals 12B of the second semiconductor chip 10B using bonding wires.

The second semiconductor chip 10B is connected to the third semiconductor chip 10C by connecting the plurality of terminals 12B of the second semiconductor chip 10B to the plurality of terminals 12C of the third semiconductor chip 10C using bonding wires.

The third semiconductor chip 10C is connected to the fourth semiconductor chip 10D by connecting the plurality of terminals 12C of the third semiconductor chip 10C to the plurality of terminals 12D of the fourth semiconductor chip 10D using bonding wires.

The twelfth bonding pad 3I, the thirteenth bonding pad 3J, the fourteenth bonding pad 3K, the fifteenth bonding pad 3L, the sixteenth bonding pad 3M, the seventeenth bonding pad 3N, the eighteenth bonding pad 3O, and the nineteenth bonding pad 3P are each connected to the plurality of terminals 12E of the fifth semiconductor chip 10E.

The fifth semiconductor chip 10E is connected to the sixth semiconductor chip 10F by connecting the plurality of terminals 12E of the fifth semiconductor chip 10E to the plurality of terminals 12F of the sixth semiconductor chip 10F using bonding wires.

The sixth semiconductor chip 10F is connected to the seventh semiconductor chip 10G by connecting the plurality of terminals 12F of the sixth semiconductor chip 10F to the plurality of terminals 12G of the seventh semiconductor chip 10G using bonding wires.

The seventh semiconductor chip 10G is connected to the eighth semiconductor chip 10H by connecting the plurality of terminals 12G of the seventh semiconductor chip 10G to the plurality of terminals 12H of the eighth semiconductor chip 10H using bonding wires.

A bonding pad group including the first bonding pad 2A and a terminal group including the terminal 12A are metal films including films that include one or more types selected from a group consisting of Cu, Ni, W, Au, Ag, Pd, Sn, Bi, Zn, Cr, Al, Ti, Ni—P, and Ni—B. Surface layers of the bonding pad group including the first bonding pad 2A and the terminal group including the terminal 12A preferably include one or more types selected from a group consisting of Au, Pd, Ni, and Cu. The surface layer is connected to a connection wiring. In the bonding pad group including the first bonding pad 2A and the terminal group including the terminal 12A, more specifically, a Ni plating and an Au plating are formed on a Cu layer. In a layer configuration of the bonding pad group including the first bonding pad 2A and the terminal group including the terminal 12A, an appropriate material is selected according to a material of the bonding wire.

The first bonding pad 2A provided on the wiring substrate 1 is a power terminal or a signal terminal, and is preferably a power terminal. A connection wiring including a first bonding wire 4A and a second bonding wire 4B and further freely including a third bonding wire 4C connects the first bonding pad 2A to the first semiconductor element 10. In the first bonding pad 2A, a plurality of bonding wires are provided. The number of bonding wires connected to the first bonding pad 2A may be two, or may be four or more. A connection wiring including the first bonding wire 4A and the second bonding wire 4B and further freely including the third bonding wire 4C is, for example, a power wiring or a signal wiring, and is preferably a power wiring.

The first bonding pad 2A is connected to the first semiconductor element 10 via the first bonding wire 4A, the second bonding wire 4B, and the third bonding wire 4C. On the first semiconductor element 10, two bonding wires selected from a group consisting of the first bonding wire 4A, the second bonding wire 4B, and the third bonding wire 4C are not connected to each other.

The first bonding wire 4A, the second bonding wire 4B, and the third bonding wire 4C are similar wirings.

The first bonding wire 4A includes a bump (ball) 4AA provided on the first bonding pad 2A, a wire 4AB, a bump 4AC provided on the terminal 12A of the first semiconductor chip 10A, a wire 4AD, a bump 4AE provided on the terminal 12B of the second semiconductor chip 10B, a wire 4AF, a bump 4AG provided on the terminal 12C of the third semiconductor chip 10C, a wire 4AH, and a bump 4AI provided on the terminal 12D of the fourth semiconductor chip 10D.

The first bonding wire 4A includes one or more types selected from a group consisting of Au, Ag, Cu, and Pd. A wire portion of the first bonding wire 4A is preferably an Au wire, an Ag wire, a Cu wire, or a Cu wire plated with Pd.

The wire 4AB connects the bump 4AA to the bump 4AC. The wire 4AB connects the first bonding pad 2A to the first semiconductor chip 10A.

The wire 4AD connects the bump 4AC to the bump 4AE. The wire 4AD connects the first semiconductor chip 10A to the second semiconductor chip 10B.

The wire 4AF connects the bump 4AE to the bump 4AG. The wire 4AF connects the second semiconductor chip 10B to the third semiconductor chip 10C.

The wire 4AH connects the bump 4AG to the bump 4AI. The wire 4AF connects the third semiconductor chip 10C to the fourth semiconductor chip 10D.

The bump 4AC, the bump 4AE, the bump 4AG, and the bump 4AI on the first semiconductor element 10 side may be omitted. Further, the bump 4AA on the first bonding pad 2A may be omitted. That is, a shape of a connection portion of the bonding wire connecting the first semiconductor element 10 to the wiring substrate 1 may be not only a ball bonding shape but also a wedge bonding shape.

The bump 4AA on the first bonding pad 2A and the bump 4AC, the bump 4AE, the bump 4AG, and the bump 4AI on the first semiconductor element 10 side may be omitted. That is, a shape of a connection portion of the bonding wire connecting the first semiconductor element 10 to the wiring substrate 1 may be not only a ball bonding shape but also a wedge bonding shape.

Protrusions are provided on the first bonding pad 2A. As the protrusions, a first bump 5A, a second bump 5B, and a third bump 5C are provided on the first bonding pad 2A. In the schematic view of FIG. 1, the first bonding wire 4A, the second bonding wire 4B, and the third bonding wire 4C are located between the first bump 5A, the second bump 5B, and the third bump 5C, and the first semiconductor element 10.

The first bump 5A, the second bump 5B, and the third bump 5C that are the protrusions include one or more metals selected from a group consisting of Au, Ag, Cu, Pd, and Sn, or resin. The protrusions are, for example, wiring materials used when the bonding wires are formed. The protrusions are, for example, solders. As the resin of the protrusions, for example, an acrylic-based resin, a phenol-based resin, and an epoxy-based resin are preferable. The resin preferably has high binding property with respect to both a mold resin and the bonding pad. The first bump 5A, the second bump 5B, and the third bump 5C that are the protrusions may contain elements included in the surface of the first bonding pad 2A. The protrusions may not contain elements included in the surface of the first bonding pad 2A.

The second bonding wire 4B is connected to a terminal of the first semiconductor element 10 different from a terminal of the first semiconductor element 10 to which the first bonding wire 4A is connected. In the schematic view of FIG. 2, the second bonding wire 4B is connected to a terminal displaced in the −X direction from the terminal of the first semiconductor element 10 to which the first bonding wire 4A is connected.

The third bonding wire 4C is connected to a terminal of the first semiconductor element 10 different from the terminal of the first semiconductor element 10 to which the first bonding wire 4A is connected and the terminal of the first semiconductor element 10 to which the second bonding wire 4B is connected. In the schematic view of FIG. 2, the third bonding wire 4C is connected to a terminal displaced in the −X direction from the terminal of the first semiconductor element 10 to which the first bonding wire 4A is connected and displaced in the +X direction from the terminal of the first semiconductor element 10 to which the second bonding wire 4B is connected.

The second bonding pad 3A provided on the wiring substrate 1 is adjacent to the first bonding pad 2A. The second bonding pad 3A is a power terminal or a signal terminal. The first bonding pad 2A and the second bonding pad 3A are arranged in a first direction oriented along a surface direction of the first bonding pad 2A. The first direction preferably includes the X direction and a substantial X direction. The first direction is a direction of a line segment connecting a center of the first bonding pad 2A to a center of the second bonding pad 3A. The second bonding pad 3A is connected to the first semiconductor element 10 via a fourth bonding wire 6A. Relationships between the first bonding pad 2A, the second bonding pad 3A, and the fourth bonding wire 6A respectively correspond to relationships between the eleventh bonding pad 2B, the twelfth bonding pad 3I, and a fifteenth bonding wire 6I provided on the opposite side on the wiring substrate 1.

The fourth bonding pad 3B provided on the wiring substrate 1 is adjacent to the second bonding pad 3A. The fourth bonding pad 3B is a power terminal or a signal terminal. The second bonding pad 3A and the fourth bonding pad 3B are arranged in the first direction. The fourth bonding pad 3B is connected to the first semiconductor element 10 via a fifth bonding wire 6B. Relationships between the second bonding pad 3A, the fourth bonding pad 3B, and the fifth bonding wire 6B respectively correspond to relationships between the twelfth bonding pad 3I, the thirteenth bonding pad 3J, and a sixteenth bonding wire 6J provided on the opposite side to the wiring substrate 1.

The fifth bonding pad 3C provided on the wiring substrate 1 is adjacent to the fourth bonding pad 3B. The fifth bonding pad 3C is a power terminal or a signal terminal. The fourth bonding pad 3B and the fifth bonding pad 3C are arranged in the first direction. The fifth bonding pad 3C is connected to the first semiconductor element 10 via a sixth bonding wire 6C. Relationships between the fourth bonding pad 3B, the fifth bonding pad 3C, and the sixth bonding wire 6C respectively correspond to relationships between the thirteenth bonding pad 3J, the fourteenth bonding pad 3K, and a seventeenth bonding wire 6K provided on the opposite side on the wiring substrate 1.

The sixth bonding pad 3D provided on the wiring substrate 1 is adjacent to the first bonding pad 2A. The first bonding pad 2A is located between the sixth bonding pad 3D and the second bonding pad 3A. The sixth bonding pad 3D is located on a side opposite to the second bonding pad 3A side in the first bonding pad 2A. The sixth bonding pad 3D is a power terminal or a signal terminal. The first bonding pad 2A and the sixth bonding pad 3D are arranged in the first direction. The sixth bonding pad 3D is connected to the first semiconductor element 10 via a seventh bonding wire 6D. Relationships between the first bonding pad 2A, the sixth bonding pad 3D, and the seventh bonding wire 6D respectively correspond to relationships between the eleventh bonding pad 2B, the fifteenth bonding pad 3L, and an eighteenth bonding wire 6L provided on the opposite side on the wiring substrate 1.

The seventh bonding pad 3E provided on the wiring substrate 1 is adjacent to the sixth bonding pad 3D. The seventh bonding pad 3E is a power terminal or a signal terminal. The sixth bonding pad 3D and the seventh bonding pad 3E are arranged in the first direction. The seventh bonding pad 3E is connected to the first semiconductor element 10 via an eighth bonding wire 6E. Relationships between the sixth bonding pad 3D, the seventh bonding pad 3E, and the eighth bonding wire 6E respectively correspond to relationships between the fifteenth bonding pad 3L, the sixteenth bonding pad 3M, and a nineteenth bonding wire 6M provided on the opposite side on the wiring substrate 1.

The eighth bonding pad 3F provided on the wiring substrate 1 is adjacent to the seventh bonding pad 3E. The eighth bonding pad 3F is a power terminal or a signal terminal. The seventh bonding pad 3E and the eighth bonding pad 3F are arranged in the first direction. The eighth bonding pad 3F is connected to the first semiconductor element 10 via a ninth bonding wire 6F. Relationships between the seventh bonding pad 3E, the eighth bonding pad 3F, and the ninth bonding wire 6F respectively correspond to relationships between the sixteenth bonding pad 3M, the seventeenth bonding pad 3N, and a twentieth bonding wire 6N provided on the opposite side on the wiring substrate 1.

The ninth bonding pad 3G provided on the wiring substrate 1 is adjacent to the eighth bonding pad 3F. The ninth bonding pad 3G is a power terminal or a signal terminal. The eighth bonding pad 3F and the ninth bonding pad 3G are arranged in the first direction. The ninth bonding pad 3G is connected to the first semiconductor element 10 via a tenth bonding wire 6G. Relationships between the eighth bonding pad 3F, the ninth bonding pad 3G, and the tenth bonding wire 6G respectively correspond to relationships between the seventeenth bonding pad 3N, the eighteenth bonding pad 3O, and a twenty-first bonding wire 6O provided on the opposite side on the wiring substrate 1.

The tenth bonding pad 3H provided on the wiring substrate 1 is adjacent to the ninth bonding pad 3G. The tenth bonding pad 3H is a power terminal or a signal terminal. The ninth bonding pad 3G and the tenth bonding pad 3H are arranged in the first direction. The tenth bonding pad 3H is connected to the first semiconductor element 10 via an eleventh bonding wire 6H. Relationships between the ninth bonding pad 3G, the tenth bonding pad 3H, and the eleventh bonding wire 6H respectively correspond to relationships between the eighteenth bonding pad 3O, the nineteenth bonding pad 3P, and a twenty-second bonding wire 6P provided on the opposite side on the wiring substrate 1.

The eleventh bonding pad 2B provided on the wiring substrate 1 is a power terminal or a signal terminal, and is preferably a power terminal. The eleventh bonding pad 2B is located on a side opposite to the first bonding pad 2A side in the first semiconductor element 10, that is, located on the opposite side of the first semiconductor element 10 in the Y direction. A connection wiring including a twelfth bonding wire 4D and a thirteenth bonding wire 4E and further freely including a fourteenth bonding wire 4F connects the eleventh bonding pad 2B to the first semiconductor element 10. In the eleventh bonding pad 2B, a plurality of bonding wires are provided. The number of bonding wires connected to the eleventh bonding pad 2B may be two, or four or more. The connection wiring including the twelfth bonding wire 4D and the thirteenth bonding wire 4E and further freely including the fourteenth bonding wire 4F is, for example, a power wiring or a signal wiring, and is preferably a power wiring.

The eleventh bonding pad 2B is connected to the first semiconductor element 10 via the twelfth bonding wire 4D, the thirteenth bonding wire 4E, and the fourteenth bonding wire 4F. On the first semiconductor element 10, two bonding wires selected from a group consisting of the twelfth bonding wire 4D, the thirteenth bonding wire 4E, and the fourteenth bonding wire 4F are not connected to each other.

The twelfth bonding wire 4D includes a bump (ball) 4DA provided on the eleventh bonding pad 2B, a wire 4DB, a bump 4DC provided on the terminal 12E of the fifth semiconductor chip 10E, a wire 4DD, a bump 4DE provided on the terminal 12F of the sixth semiconductor chip 10F, a wire 4DF, a bump 4DG provided on the terminal 12G of the seventh semiconductor chip 10G, a wire 4DH, and a bump 4DI provided on the terminal 12H of the eighth semiconductor chip 10H.

The twelfth bonding wire 4D includes one or more types selected from a group consisting of Au, Ag, Cu, and Pd. A wire portion of the twelfth bonding wire 4D is preferably an Au wire, an Ag wire, a Cu wire, or a Cu wire plated with Pd.

The wire 4DB connects the bump 4DA to the bump 4DC. The wire 4DB connects the eleventh bonding pad 2B to the fifth semiconductor chip 10E.

The wire 4DD connects the bump 4DC to the bump 4DE. The wire 4DD connects the fifth semiconductor ship 10E to the sixth semiconductor chip 10F.

The wire 4DF connects the bump 4DE to the bump 4DG. The wire 4DF connects the sixth semiconductor chip 10F to the seventh semiconductor chip 10G.

The wire 4DH connects the bump 4DG to the bump 4DI. The wire 4DH connects the seventh semiconductor chip 10G to the eighth semiconductor chip 10H.

Protrusions are provided on the eleventh bonding pad 2B. As the protrusions, a fourth bump 5D, a fifth bump 5E, and a sixth bump 5F are provided on the eleventh bonding pad 2B. In the schematic view of FIG. 1, the twelfth bonding wire 4D, the thirteenth bonding wire 4E, and the fourteenth bonding wire 4F are located between the fourth bump 5D, the fifth bump 5E, the sixth bump 5F, and the first semiconductor element 10.

The fourth bump 5D, the fifth bump 5E, and the sixth bump 5F that are the protrusions include one or more metals selected from a group consisting of Au, Ag, Cu, Pd, and Sn, or resin. The protrusions are, for example, wiring materials used when the bonding wires are formed. The protrusions are, for example, solders. As the resin of the protrusions, for example, an acrylic-based resin, a phenol-based resin, and an epoxy-based resin are preferable. The protrusions may contain elements contained in the surface of the eleventh bonding pad 2B. The protrusions may not contain elements contained in the surface of the eleventh bonding pad 2B.

The thirteenth bonding wire 4E is connected to a terminal of the first semiconductor element 10 different from a terminal of the first semiconductor element 10 to which the twelfth bonding wire 4D is connected. In the schematic view of FIG. 2, the thirteenth bonding wire 4E is connected to a terminal displaced in the +X direction from the terminal of the first semiconductor element 10 to which the twelfth bonding wire 4D is connected.

The fourteenth bonding wire 4F is connected to a terminal of the first semiconductor element 10 different from the terminal of the first semiconductor element 10 to which the twelfth bonding wire 4D is connected and the terminal of the first semiconductor element 10 to which the thirteenth bonding wire 4E is connected. In the schematic view of FIG. 2, the fourteenth bonding wire 4F is connected to a terminal displaced in the +X direction from the terminal of the first semiconductor element 10 to which the twelfth bonding wire 4D is connected and displaced in the −X direction from the terminal of the first semiconductor element 10 to which the thirteenth bonding wire 4E is connected.

The solder ball 7 is a terminal electrically connected to the outside of the semiconductor device 100.

The encapsulant 8 seals the first semiconductor element 10, the first bonding pad 2A, the second bonding pad 3A, the bonding wire, and the like. The encapsulant 8 is, for example, a mold resin. As the mold resin, for example, a naphthalene-type epoxy resin and a dicyclopentadiene-type epoxy resin are preferable. Further, a benzophenone-type epoxy resin is preferable since the benzophenone-type epoxy resin can easily obtain fast curability. The epoxy resin may be used alone or two or more types of epoxy resins may be used in combination. A filler such as silica or alumina may be provided in the encapsulant 8.

The second semiconductor element 21 is, for example, a semiconductor chip that controls reading, writing, erasing, and the like of the first semiconductor element 10. The second semiconductor element 21 is surrounded by the first insulating layer 40 and is covered with the second insulating layer 41 provided between the first semiconductor element 10 and the second semiconductor element 21. The schematic view of FIG. 2 illustrates an example of a position at which the second semiconductor element 21 is disposed.

The second semiconductor element 21 is connected to the first semiconductor element 10 via the wiring substrate 1. The second semiconductor element 21 is connected by, for example, bonding wires. A terminal 22 on the second semiconductor element 21 is connected to a terminal 27 on the wiring substrate 1 by a wire 26 via a bump 23 and a bump 28, respectively. A terminal 24 on the second semiconductor element 21 is connected to a terminal 30 on the wiring substrate 1 by a wire 29 via a bump 25 and a bump 31, respectively. A power supply or the like may be enhanced in a power system of the second semiconductor element 21 by adopting the first bonding pad 2A and the connection thereof.

The bump 23 and the bump 25 may be omitted. Further, the bump 28 and the bump 31 may be omitted.

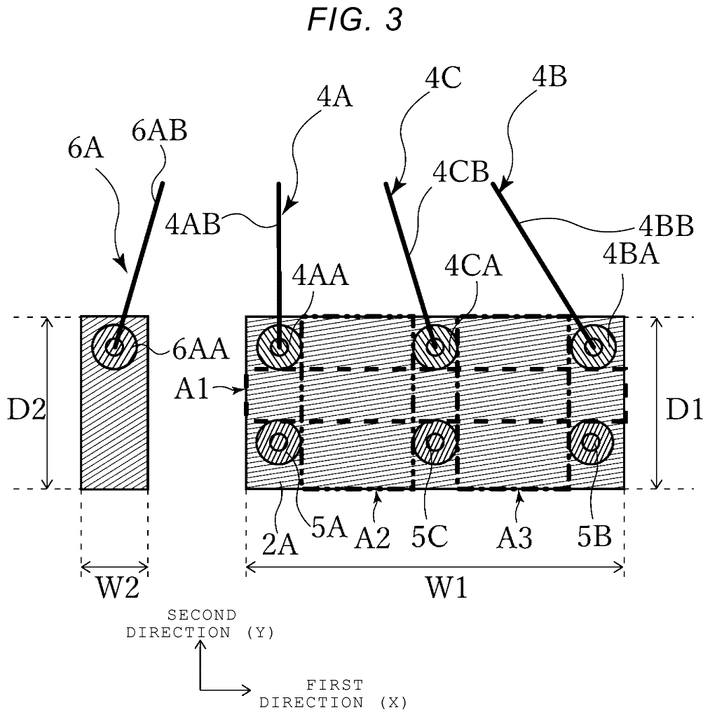

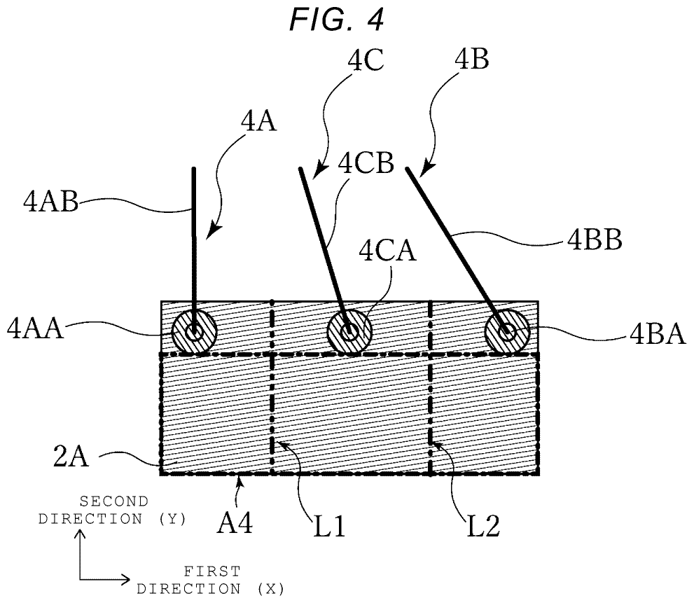

Next, the first bonding pad 2A and the bonding wire thereof will be described with reference to the schematic view of the vicinity of the first bonding pad 2A of the semiconductor device 100 in FIG. 3. The description will be made below with reference to FIG. 4 that is a schematic view of the first bonding pad of the semiconductor device as a reference. Hereinafter, the first bonding pad 2A will be described and the description of the first bonding pad 2A and the connection wiring thereof also corresponds to the description of the eleventh bonding pad 2B and the connection wiring thereof.

In the schematic view of FIG. 3, the first bonding pad 2A and the second bonding pad 3A are enlarged. The first bonding pad 2A and the second bonding pad 3A may extend straight in a second direction or may extend in a direction having a different angle from the second direction. In description, a configuration in which the first bonding pad 2A and the second bonding pad 3A extend straight in the second direction is adopted for simplicity.

The fourth bonding wire 6A includes a bump 6AA and a wire 6AB.

Since the first bonding pad 2A includes the first bonding wire 4A, the second bonding wire 4B, and the third bonding wire 4C arranged in the first direction, the length of the first bonding pad 2A in the first direction is longer than that of the second bonding pad 3A. Therefore, when a protrusion is not provided, as illustrated in FIG. 4, an area A4 of a region that is not partitioned in a non-connection region where the first bonding pad 2A is not connected by a connection wire becomes larger.

When the length of the first bonding pad 2A is specifically defined, a length of the first bonding pad 2A in the first direction is W1 and a direction intersecting the first direction on the surface of the first bonding pad 2A is referred to as a second direction. A direction orthogonal to the first direction on the surface of the first bonding pad 2A is preferably set to the second direction. A length of the first bonding pad 2A in the second direction is D1. Here, for example, W1 is 0.5 times or more or 5 times or less of D1. When the first bonding pad 2A is long in the first direction, W1 is preferably 1.5 times or more and 5 times or less of D1.

When a length of the second bonding pad 3A is specifically defined, a length of the second bonding pad 3A in the first direction is W2 and a length of the second bonding pad 3A in the second direction is D2. Here, for example, D2 is 1.5 times or more and 15 times or less of W2.

When the area of the pad becomes larger, an area of a region not in contact with the connection wiring becomes larger in a surface of a side on which the connection wiring of the first bonding pad 2A is provided. Since the surface of the first bonding pad 2A is a metal surface such as a gold plating, a binding property between the first bonding pad 2A and the encapsulant 8 tends to be lower than a binding property between the second bonding pad 3A and the encapsulant 8. Accordingly, even when the first bonding pad 2A having a configuration in which a power supply is enhanced is adopted, durability and/or reliability of the semiconductor device 100 can be improved by partitioning the non-connection region not connected to the connection wiring of the first bonding pad 2A so that the binding property between the first bonding pad 2A and the encapsulant 8 becomes similar to the binding property between the second bonding pad 3A and the encapsulant 8.

An area A1 (an area of a region surrounded by a broken line in FIG. 3, that is, a rectangular region that has long sides in the first direction and is located on the inner side with respect to the bump 4AA of the first bonding wire 4A, a bump 4BA of the second bonding wire 4B, a bump 4CA of the third bonding wire 4C, the first bump 5A, the second bump 5B, and the third bump 5C on the surface of the first bonding pad 2A), an area A2 (an area of a region surrounded by a two-dot short chain line in FIG. 3, that is, a rectangular region that has long sides in the second direction and is located on the inner side with respect to the bump 4AA of the first bonding wire 4A, the bump 4CA of the third bonding wire 4C, the first bump 5A, and the third bump 5C on the surface of the first bonding pad 2A), and an area A3 (an area of a region surrounded by a one-dot short chain line in FIG. 3, that is, a rectangular region that has long sides in the second direction and is located on the inner side with respect to the bump 4BA of the second bonding wire 4B, the bump 4CA of the third bonding wire 4C, the second bump 5B, and the third bump 5C on the surface of the first bonding pad 2A) of the partitioned regions of the first bonding pad 2A are each less than an area A4 (an area of a region surrounded by a one-dot two-short chain line in FIG. 4, that is, a maximum rectangular region that has long sides in the first direction and is located closer to the side in the +Y direction than the bump 4AA of the first bonding wire 4A, the bump 4BA of the second bonding wire 4B, and the bump 4CA of the third bonding wire 4C on the surface of the first bonding pad 2A). Therefore, it is conceivable that contraction and expansion stress between the encapsulant 8 and the first bonding pad 2A is dispersed. A sum of the area A1, the area A2, and the area A3 is relatively large, but a decrease in each area contributes to an improvement in durability or/and reliability.

For example, the non-connection region regarding the connection wiring of the first bonding pad 2A is partitioned by providing protrusions on a surface layer of the first bonding pad 2A. Preferably, a plurality of protrusions are provided on the first bonding pad 2A. As examples of the protrusions, a form in which the first bump 5A, the second bump 5B, and the third bump 5C are provided on the first bonding pad 2A is illustrated in the schematic view of FIG. 3. The protrusions are not limited to bumps (dummy bumps) as long as the protrusions are projections provided on the surface of the first bonding pad 2A. The first bonding pad 2A itself has minute unevenness, but it is conceivable that the region is partitioned and contraction and expansion stress is dispersed by providing the protrusions.

The first bump 5A, the second bump 5B, and the third bump 5C are lined up in the first direction (the X direction), and are lined up at the same Y coordinate or substantially the same Y coordinate with almost no displacement in the second direction (the Y direction). The third bump 5C is interposed between the first bump 5A and the second bump 5B in the first direction. The first bump 5A and the bump 4AA of the first bonding wire 4A are lined up in the second direction and have the same X coordinate or substantially the same X coordinate. The second bump 5B and the bump 4BA of the second bonding wire 4B are lined up in the second direction and have the same X coordinate or substantially the same X coordinate. The third bump 5C is provided at a position of middle or substantial middle of W1 from an end of the first bonding pad 2A in the first direction. The third bump 5C and the bump 4CA of the third bonding wire 4C are lined up in the second direction and have the same X coordinate or substantially the same X coordinate. A distance between the first bump 5A and the third bump 5C in the first direction is the same or substantially the same as a distance between the second bump 5B and the third bump 5C in the first direction. A distance between the first bump 5A and the bump 4AA of the first bonding wire 4A in the second direction is the same or substantially the same as a distance between the second bump 5B and the bump 4BA of the second bonding wire 4B in the second direction or/and a distance between the third bump 5C and the bump 4CA of the third bonding wire 4C in the second direction.

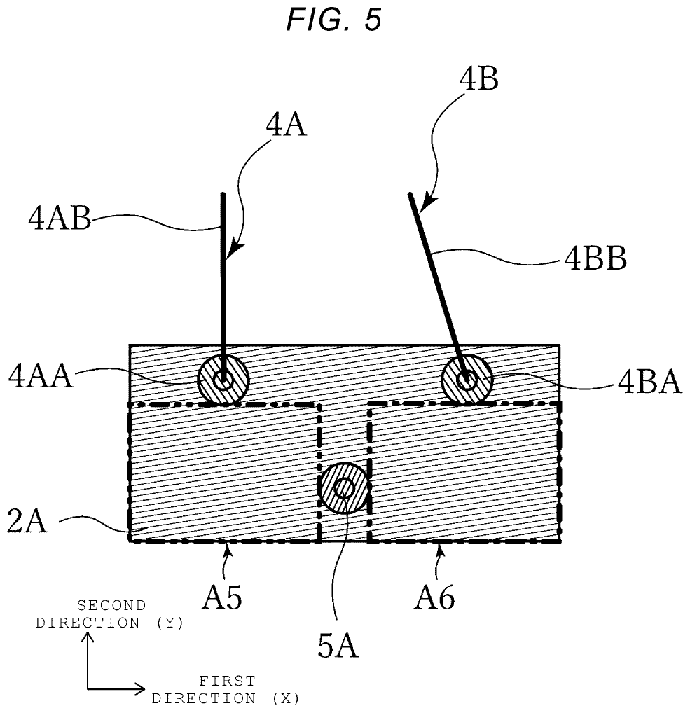

FIG. 5 is a schematic view illustrating the first bonding pad 2A of the semiconductor device 100. In the first bonding pad 2A illustrated in the schematic view of FIG. 5, a connection wiring including two bonding wires is provided and one first bump 5A is provided, and thus a non-connection region regarding the connection wiring of the first bonding pad 2A can be partitioned validly. An area A5 (an area of a region surrounded by a two-dot short chain line in FIG. 5, that is, a rectangular region that has long sides in the first direction and is located on the −X direction side of the bump 4AA of the first bonding wire 4A and the first bump 5A on the surface of the first bonding pad 2A) and an area A6 (an area of a region surrounded by a one-dot short chain line in FIG. 5, that is, a rectangular region that has long sides in the first direction and is located on the +X direction side of the bump 4BA of the second bonding wire 4B and the first bump 5A on the surface of the first bonding pad 2A) are each sufficiently smaller than the area A4. The form illustrated in the schematic view of FIG. 5 is also preferable from the viewpoint of an improvement in durability or/and reliability.

When a protrusion is provided to partition an area, a maximum rectangular area in a region not in contact with the connection wiring and the protrusion is preferably 70% or less of A4 and more preferably 10% or more and 60% or less of A4 assuming that A4 is a maximum rectangular area in a region not in contact with the connection wiring of the first bonding pad 2A on a surface of a side on which the connection wiring of the first bonding pad 2A is provided.

The protrusion is preferably provided at a position close to the center of the first bonding pad 2A from the viewpoint of an improvement in durability or/and reliability. Specifically, one or more protrusions are preferably located in a region inside a virtual circle that has a diameter of ¾ of D1 from the center of the first bonding pad 2A, and one or more protrusions are located in a region inside a virtual circle that has a diameter of ½ of D1.

The number of protrusions is not particularly limited, and for example, the number of protrusions is preferably equal to or less than the number of bonding wires included in the connection wiring provided in the first bonding pad 2A.

The connection wiring of the first bonding pad 2A is located on the first semiconductor element 10 side and the protrusion is located opposite to the first semiconductor element 10 side. When the positional relationship is satisfied, a wiring length of the connection wiring becomes shorter, which contributes to lower inductance of the connection wiring.

When a ball bonding bump is adopted as a protrusion, adhesion between the protrusion and the encapsulant 8 is improved by the anchor effect. The improvement in adhesion between the protrusion and the encapsulant 8 results in a favorable improvement in durability or/and reliability of the semiconductor device 100.

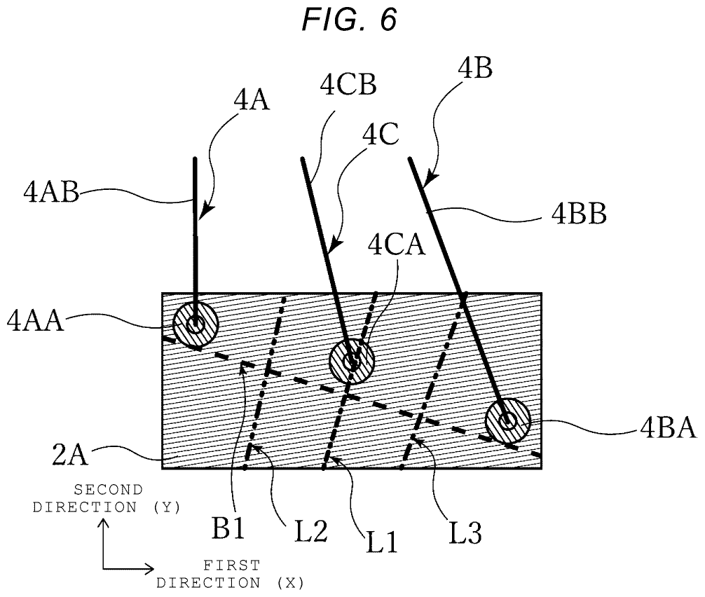

As a form in which the non-connection region regarding the connection wiring of the first bonding pad 2A is partitioned, a form in which the region not connected by the connection wiring is partitioned in a non-perpendicular direction with respect to the first direction is also preferable. A form in which the region not connected by the connection wiring is partitioned in a non-perpendicular direction with respect to the first direction will be described with reference to the schematic view of the first bonding pad 2A of the semiconductor device 100 in FIGS. 6, 7, and 8.

By displacing a part of the plurality of bonding wires included in the connection wiring of the first bonding pad 2A in the second direction, it is possible to partition the non-connection region regarding the connection wiring of the first bonding pad 2A in a non-perpendicular direction with respect to the first direction. That is, by separating the plurality of bonding wires included in the connection wiring of the first bonding pad 2A in the second direction, it is possible to partition the non-connection region regarding the connection wiring of the first bonding pad 2A in a non-perpendicular direction with respect to the first direction.

In the first bonding pad 2A illustrated in the schematic view of FIG. 6, all of the first bonding wire 4A, the second bonding wire 4B, and the third bonding wire 4C are displaced in the second direction relative to each other. Due to the displacement in the second direction, the region is partitioned so that the non-connection region regarding the connection wiring of the first bonding pad 2A becomes small. FIG. 6 illustrates, for example, a configuration in which the first bonding wire 4A is provided with the bump 4AA. However, when the first bonding wire 4A or the like is formed by wedge bonding, the displacement in the second direction can be evaluated by treating an elongated connection surface between the bonding wire and the first bonding pad 2A in the second direction as the bump 4AA in FIG. 6. A region not connected by the connection wiring of the first bonding pad 2A is partitioned in a non-perpendicular direction (in the direction of a virtual line B1) with respect to the first direction by the virtual line B1 of FIG. 6.

The bump 4BA of the second bonding wire 4B is located in the −Y direction relative to the bump 4AA of the first bonding wire 4A. The bump 4BA of the second bonding wire 4B is located in the −Y direction relative to the bump 4CA of the third bonding wire 4C. The bump 4CA of the third bonding wire 4C is located in the −Y direction relative to the bump 4AA of the first bonding wire 4A. The bump 4CA of the third bonding wire 4C is located between the bump 4AA of the first bonding wire 4A and the bump 4BA of the second bonding wire 4B in the Y direction. In the schematic view of FIG. 6, the first bonding wire 4A and the second bonding wire 4B are selected so that a displacement amount in the Y direction is the largest.

When a connection surface between the second bonding wire 4B (one or more bonding wires selected freely) and the first bonding pad 2A and a connection surface between the bonding wire most adjacent to the one or more bonding wires selected freely and the first bonding pad 2A are displaced in the second direction, the bonding wires of the connection wiring provided on the first bonding pad 2A are displaced in the second direction. The connection surface between the one or more bonding wires selected freely and the first bonding pad 2A and the connection surface between the bonding wire most adjacent to the one or more bonding wires selected freely and the first bonding pad 2A are preferably displaced in the second direction by a half or more of the length of each connection surface between the one or more bonding wires selected freely and the first bonding pad 2A. Each connection surface between the one or more bonding wires selected freely and the first bonding pad 2A and the connection surface between the bonding wire most adjacent to the one or more bonding wires selected freely and the first bonding pad 2A are more preferably displaced in the second direction by the length or more of each connection surface between the one or more bonding wires selected freely and the first bonding pad 2A in the second direction.

A virtual line L1 illustrated in the schematic view of FIG. 6 indicates a Voronoi boundary between a first base point and a second base point when the first base point is a center of a connection region between the first bonding wire 4A and the first bonding pad 2A and the second base point is a center of a connection region between the second bonding wire 4B and the first bonding pad 2A.

A virtual line L2 illustrated in the schematic view of FIG. 6 indicates a Voronoi boundary between a first base point and a third base point when the first base point is the center of the connection region between the first bonding wire 4A and the first bonding pad 2A and the third base point is a center of a connection region between the third bonding wire 4C and the first bonding pad 2A.

A virtual line L3 illustrated in the schematic view of FIG. 6 indicates a Voronoi boundary between a second base point and a third base point when the second base point is the center of the connection region between the second bonding wire 4B and the first bonding pad 2A and the third base point is the center of the connection region between the third bonding wire 4C and the first bonding pad 2A.

When angles formed by the virtual line L1, the virtual line L2, and the virtual line L3, and the first direction are 90°, a form illustrated in the schematic view of FIG. 4 is obtained. By inclining the angles formed by the virtual line L1, the virtual line L2, and the virtual line L3, and the first direction with respect to 90°, it is possible to partition the non-connection region regarding the connection wiring of the first bonding pad 2A in a non-perpendicular direction with respect to the first direction. The virtual line L1, the virtual line L2, and the virtual line L3 are illustrated in the schematic views of FIGS. 6, 7, and 8.

The angles formed by the virtual line L1, the virtual line L2, and the virtual line L3, and the first direction are preferably 45° or more and 85° or less, or 95° or more and 135° or less. When the angles are within such range, the first bonding wire 4A, the second bonding wire 4B, and the third bonding wire 4C are well-balanced in the arrangement and an area of the non-connection portions become small favorably.

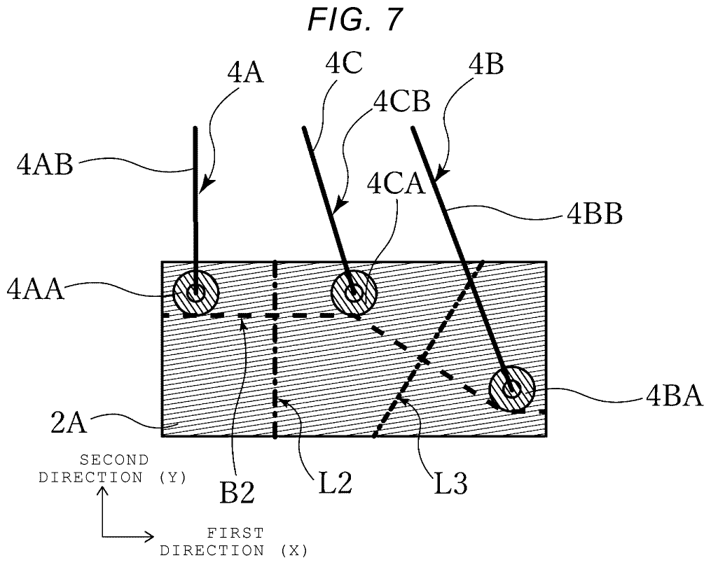

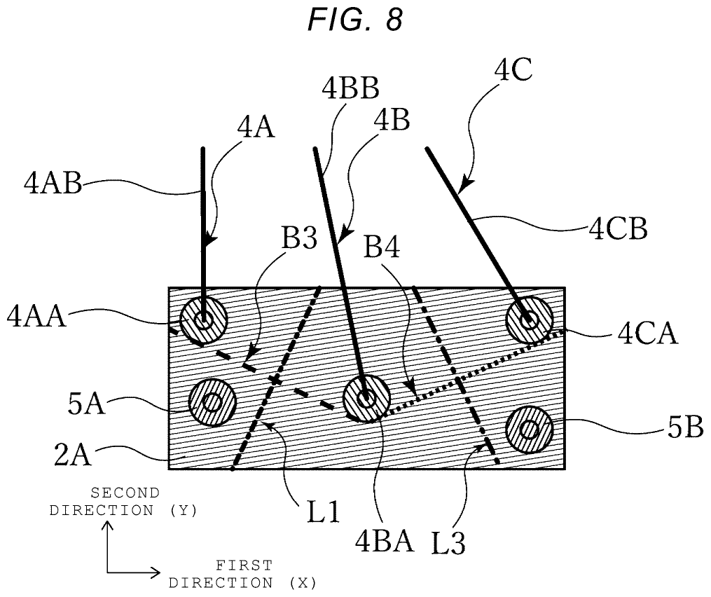

Modified examples of the form illustrated in the schematic view of FIG. 6 are illustrated in the schematic view of FIG. 7 and the schematic view of FIG. 8. In a form illustrated in the schematic view of FIG. 7, the first bonding wire 4A and the third bonding wire 4C are not displaced in the second direction. Therefore, an angle formed by the virtual line L3 and the first direction is 90°. Meanwhile, since the second bonding wire 4B is displaced from the first bonding wire 4A in the second direction, the angle formed by the virtual line L1 and the first direction is inclined with respect to 90°. When three or more bonding wires are included as connection wirings in the first bonding pad 2A, each of the first bonding wire 4A, the second bonding wire 4B, and the third bonding wire 4C is specified from the bonding wires included in the connection wiring considering the angles formed by the virtual lines and the first direction and the angles formed by the virtual lines and the first direction are evaluated. A region not connected by the connection wiring of the first bonding pad 2A is partitioned in a non-perpendicular direction (the direction of a virtual line B2) with respect to the first direction by the virtual line B2 of FIG. 7.

The bump 4BA of the second bonding wire 4B in the form illustrated in the schematic view of FIG. 7 is located in the −Y direction relative to the bump 4AA of the first bonding wire 4A. The bump 4BA of the second bonding wire 4B in the form illustrated in the schematic view of FIG. 7 is located in the −Y direction relative to the bump 4CA of the third bonding wire 4C. The bump 4CA of the third bonding wire 4C is located so that the Y coordinate of the bump 4CA of the third bonding wire 4C is the same or substantially the same as the Y coordinate of the bump 4AA of the first bonding wire 4A. In the form of the schematic view of FIG. 7 or the like, the first bonding wire 4A and the second bonding wire 4B can be selected so that a displacement amount in the Y direction is the largest.

A form illustrated in the schematic view of FIG. 8 is a form in which the plurality of bonding wires included in the connection wiring of the first bonding pad 2A are separated in the second direction, and the first bump 5A and the second bump 5B are provided as the protrusions. The methods of partitioning regions of the non-connection portions can also be combined. A region not connected by the connection wiring of the first bonding pad 2A is partitioned in a non-perpendicular direction (the direction of a virtual line B3) with respect to the first direction by the virtual line B3 of FIG. 8. A region not connected by the connection wiring of the first bonding pad 2A is partitioned in a non-perpendicular direction (the direction of a virtual line B4) with respect to the first direction by the virtual line B4 of FIG. 8.

The bump 4BA of the second bonding wire 4B in the form illustrated in the schematic view of FIG. 8 is located in the −Y direction relative to the bump 4AA of the first bonding wire 4A. The bump 4BA of the second bonding wire 4B illustrated in the schematic view of FIG. 8 is located in the −Y direction relative to the bump 4CA of the third bonding wire 4C. The bump 4CA of the third bonding wire 4C is located so that the Y coordinate of the bump 4CA of the third bonding wire 4C is the same or substantially the same as the Y coordinate of the bump 4AA of the first bonding wire 4A. In the form of the schematic view of FIG. 8, the first bonding wire 4A and the second bonding wire 4B are selected so that a displacement amount in the Y direction is the largest.

The first bump 5A in the form illustrated in the schematic view of FIG. 8 is located in the −Y direction relative to the bump 4AA of the first bonding wire 4A and is located in the −X direction relative to the bump 4BA of the second bonding wire 4B. The second bump 5B in the form illustrated in the schematic view of FIG. 8 is located in the −Y direction relative to the bump 4CA of the third bonding wire 4C and is located in the +X direction relative to the bump 4BA of the second bonding wire 4B. In the first direction, the bump 4BA of the second bonding wire 4B is located between the first bump 5A and the second bump 5B.

In all of the forms illustrated in the schematic views of FIGS. 6, 7, and 8, the regions can be partitioned so that the regions of the non-connection portions become small, and thus the forms are preferable from the viewpoint of improving durability or/and reliability.

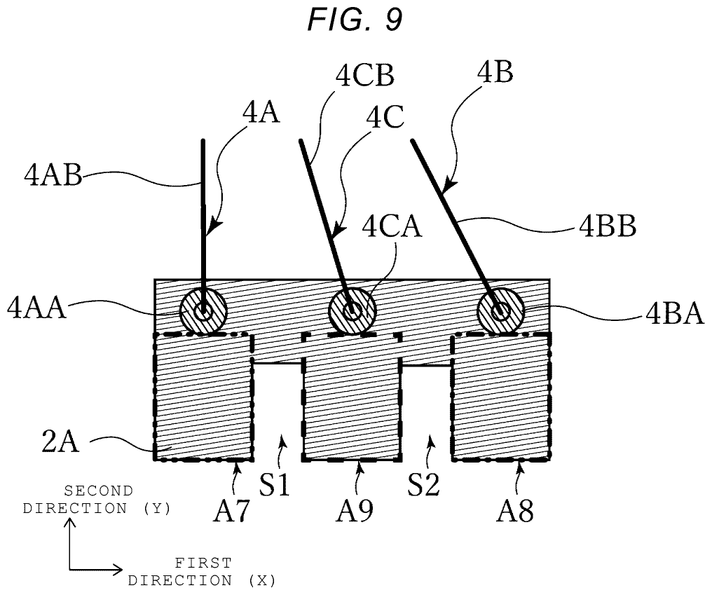

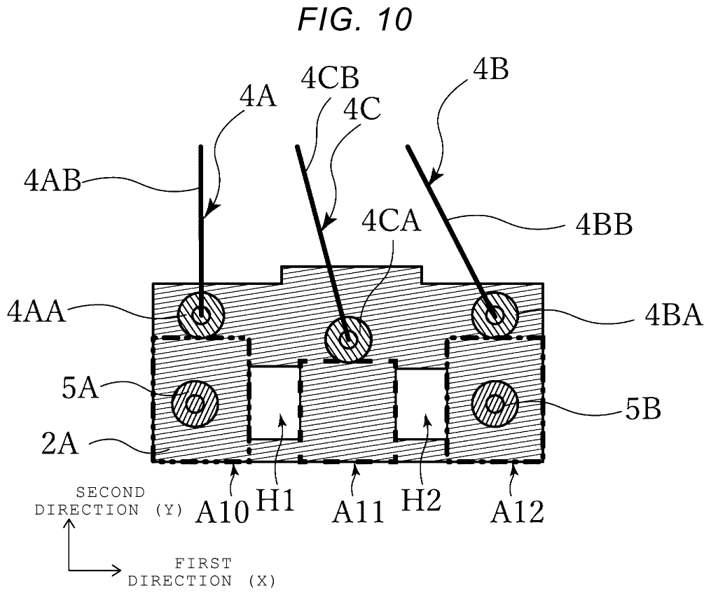

As the form in which the non-connection region regarding the connection wiring of the first bonding pad 2A is partitioned, a form in which the region not connected by the connection wiring is physically partially partitioned is preferable. A form in which the region not connected by the connection wiring is physically partially partitioned will be described with reference to the schematic views of the first bonding pad 2A of the semiconductor device 100 in FIGS. 9 and 10.

The first bonding pad 2A illustrated in the schematic view of FIG. 9 includes slits. The first bonding pad 2A illustrated in the schematic view of FIG. 9 includes a first slit S1 and a second slit S2. A non-connection region regarding the connection wiring of the first bonding pad 2A can be physically partitioned into three regions by the first slit S1 and the second slit S2. By physically partitioning the non-connection region, an area A7 (an area of a region surrounded by a two-dot short chain line in FIG. 9, that is, a rectangular region that has long sides in the second direction, is located in the −Y direction relative to the bump 4AA of the first bonding wire 4A on the surface of the first bonding pad 2A, and is located in the −X direction relative to the first slit S1), an area A8 (an area of a region surrounded by a one-dot short chain line in FIG. 9, that is, a rectangular region that has long sides in the second direction, is located in the −Y direction relative to the bump 4BA of the second bonding wire 4B on the surface of the first bonding pad 2A, and is located in the +X direction relative to the second slit S2), and an area A9 (an area of a region surrounded by a broken line in FIG. 9, that is, a rectangular region that has long sides in the second direction, is located in the −Y direction relative to the bump 4CA of the third bonding wire 4C on the surface of the first bonding pad 2A, and is located between the first slit S1 and the second slit S2) of rectangular regions not in contact with the connection wiring are validly smaller than the area A4 in the form illustrated in the schematic view of FIG. 4. By providing the first slit S1 and the second slit S2, it is possible to improve durability or/and reliability of the semiconductor device 100 without considerably reducing the area of the first bonding pad 2A. The number of slits is not limited, and for example, the number of slits is equal to or less than the number of bonding wires included in the connection wiring.

The first bonding pad 2A in the form illustrated in the schematic view of FIG. 10 includes openings. The first bonding pad 2A illustrated in the schematic view of FIG. 10 includes a first opening H1 and a second opening H2. A non-connection region regarding the connection wiring of the first bonding pad 2A can be physically partitioned into three regions by the first opening H1 and second opening H2. By physically partitioning the non-connection region, an area A10 (an area of a region surrounded by a two-dot short chain line in FIG. 10, that is, a rectangular region that has long sides in the second direction, is located in the −Y direction relative to the bump 4AA of the first bonding wire 4A on the surface of the first bonding pad 2A, and is located in the −X direction relative to the first opening H1), an area A11 (an area of a region surrounded by a broken line in FIG. 10, that is, a rectangular region that has long sides in the second direction, is located in the −Y direction relative to the bump 4CA of the third bonding wire 4C on the surface of the first bonding pad 2A, and is located between the first opening H1 and the second opening H2), and an area A12 (an area of a region surrounded by a one-dot short chain line in FIG. 10, that is, a rectangular shape that has sides in the second direction slightly longer than sides in the first direction, is located in the −Y direction relative to the bump 4BA of the second bonding wire 4B on the surface of the first bonding pad 2A, and is located in the +X direction relative to the second opening H2) of rectangular regions not in contact with the connection wiring are validly smaller than the area A4 in the form illustrated in the schematic view of FIG. 4. By providing the first opening H1 and the second opening H2, it is possible to improve durability or/and reliability of the semiconductor device 100 without considerably reducing the area of the first bonding pad 2A. The number of openings is not limited, and for example, the number of openings is equal to or less than the number of bonding wires included in the connection wiring.

As illustrated in the schematic view of FIG. 10, in the form in which the region not connected by the connection wiring is physically partially partitioned, for example, the first bump 5A and the second bump 5B can be provided as the protrusions or the bonding wires included in the connection wiring can be displaced in the second direction. The preferable forms can all be achieved in combination and contributes to an improvement in durability or/and reliability of the semiconductor device 100 in any combination. The slits and the openings can also be combined.

From the viewpoint of valid partition of the non-connection region regarding the connection wiring of the first bonding pad 2A, the slits and the openings preferably extend in the second direction.

The larger the areas of the slits and the openings, the smaller the area of the first bonding pad 2A. Therefore, a sum of the areas of the slits and the areas of the openings is preferably 5% or more and 30% or less of the area of the first bonding pad 2A.

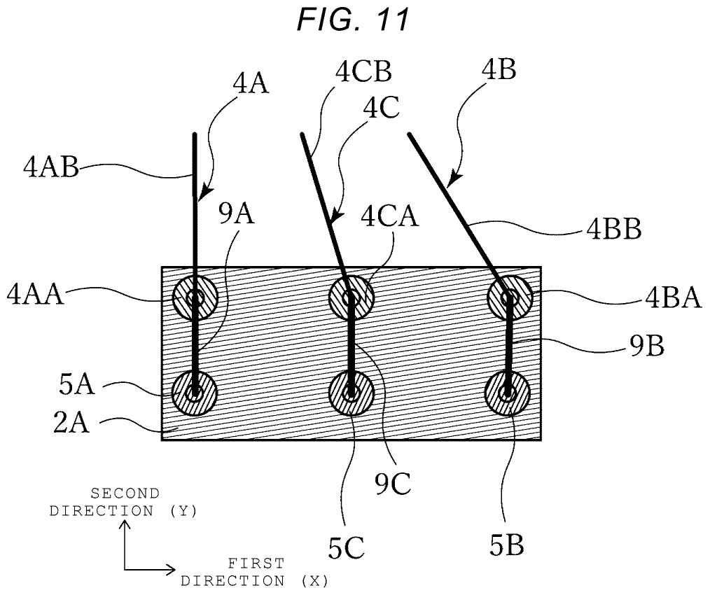

FIG. 11 is a schematic view illustrating the first bonding pad 2A of the semiconductor device 100. When the non-connection region regarding the connection wiring of the first bonding pad 2A is partitioned using the protrusions, at least one protrusion can be connected to one or more bonding wires included in the connection wiring by, for example, bonding wires or the like.

In the schematic view of FIG. 11, the first bump 5A and the bump 4AA of the first bonding wire 4A that are the protrusions are connected by a wire 9A extending in the second direction. In the schematic view of FIG. 11, the second bump 5B and the bump 4BA of the second bonding wire 4B that are the protrusions are connected by a wire 9B extending in the second direction. In the schematic view of FIG. 11, the third bump 5C and the bump 4CA of the third bonding wire 4C that are the protrusions are connected by a wire 9C extending in the second direction.

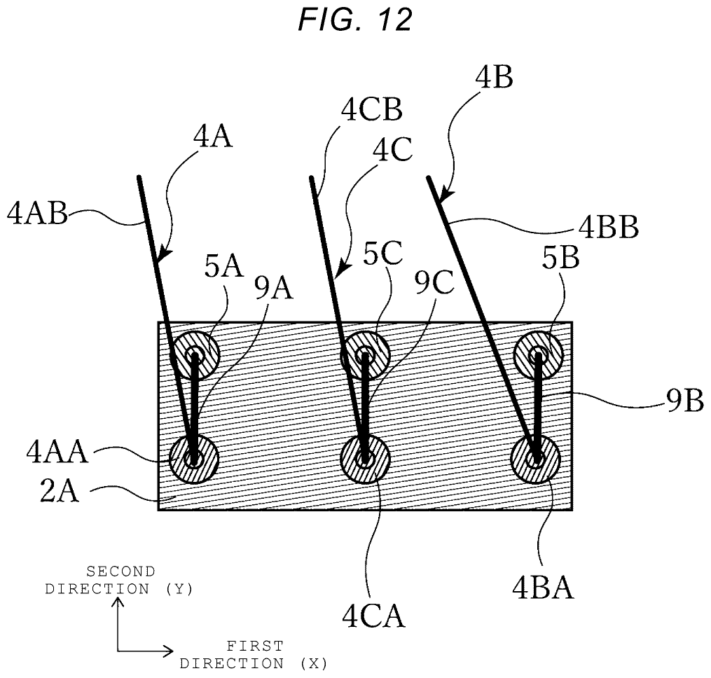

FIG. 12 is a schematic view illustrating the first bonding pad 2A of the semiconductor device 100. When the non-connection region regarding the connection wiring of the first bonding pad 2A is partitioned using the protrusions, the protrusions can also be disposed on the first semiconductor element 10 side. Here, as in the form illustrated in the schematic view of FIG. 11, the protrusions and the bonding wires of the connection wiring can be connected by wires.

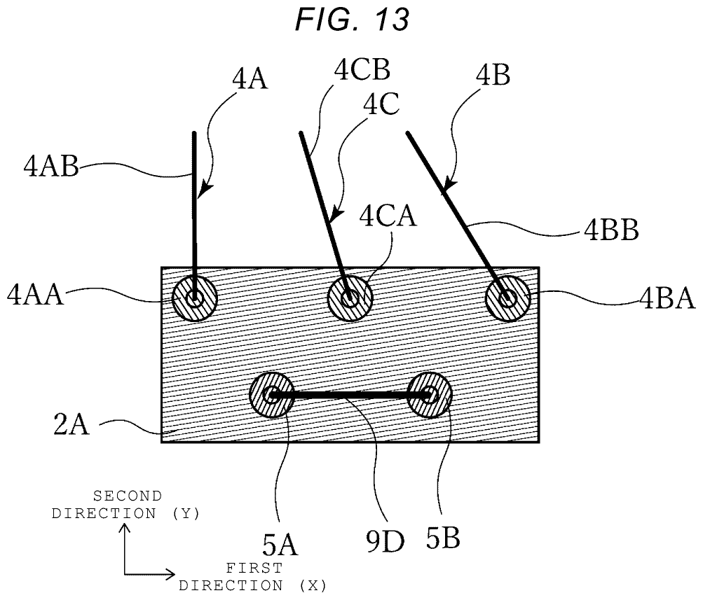

FIG. 13 is a schematic view illustrating the first bonding pad 2A of the semiconductor device 100. When the non-connection region regarding the connection wiring of the first bonding pad 2A is partitioned using the protrusions, the protrusions can be connected to each other. In the form illustrated in the schematic view of FIG. 13, the first bump 5A and the second bump 5B are connected by a wire 9D extending in the first direction.

The first bump 5A in the form illustrated in the schematic view of FIG. 13 is located in the −Y direction relative to the bump 4AA of the first bonding wire 4A and the bump 4CA of the third bonding wire 4C and is located between the bump 4AA of the first bonding wire 4A and the bump 4CA of the third bonding wire 4C in the X direction. The second bump 5B in the form illustrated in the schematic view of FIG. 13 is located in the −Y direction relative to the bump 4BA of the second bonding wire 4B and the bump 4CA of the third bonding wire 4C and is located between the bump 4BA of the second bonding wire 4B and the bump 4CA of the third bonding wire 4C in the X direction.

Even when the positions of the protrusions are changed or the protrusions are connected, the non-connection region regarding the connection wiring of the first bonding pad 2A can be validly partitioned, which contributes to an improvement in durability or/and reliability of the semiconductor device 100.

In the embodiment, durability or/and reliability of the semiconductor device 100 can be improved in various ways. Durability or/and reliability of the semiconductor device 100 can be improved without change or with a small change in a design such as wiring layout in the already designed wiring substrate 1.

### Second Embodiment

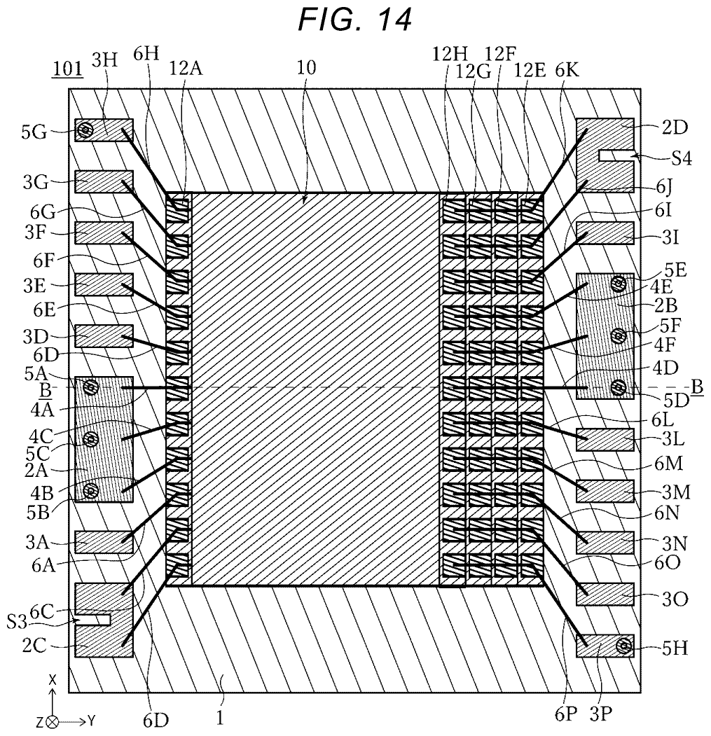

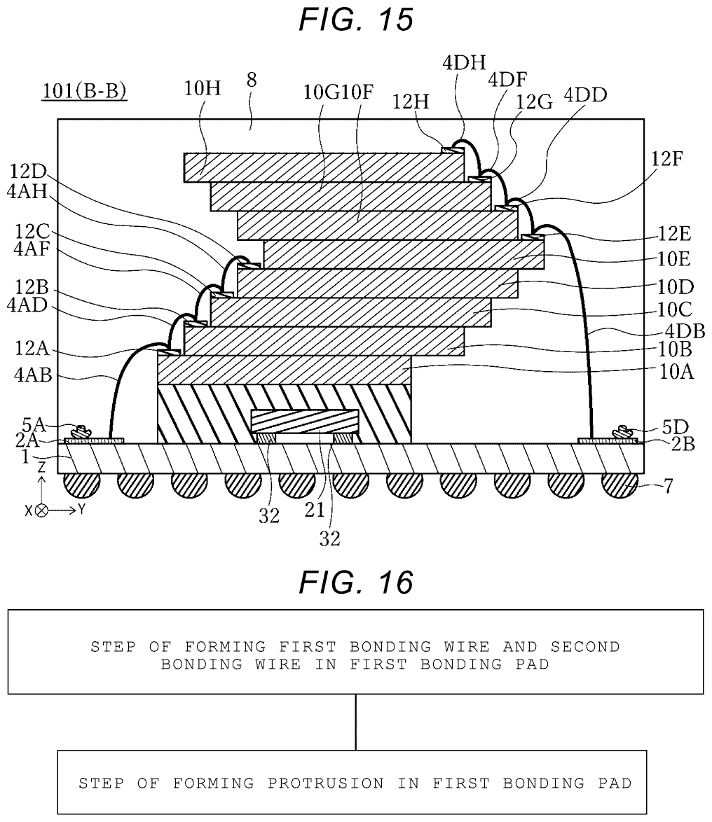

A second embodiment relates to a semiconductor device. The second embodiment is a modified example of the semiconductor device 100 of the first embodiment. FIGS. 14 and 15 are schematic views illustrating a semiconductor device 101 according to the second embodiment. The schematic view of FIG. 15 is a schematic sectional view taken along a line B-B of FIG. 14. Description of common contents between the first embodiment and the second embodiment will be omitted.

The semiconductor 101 is different from the semiconductor device 100 in that bumps are not used in bonding wires, a third bonding pad 2C is used instead of the fourth bonding pad 3B and the fifth bonding pad 3C, a twentieth bonding pad 2D is used instead of the thirteenth bonding pad 3J and the fourteenth bonding pad 3K, a seventh bump 5G is provided in the tenth bonding pad 3H, an eighth bump 5H is provided in the nineteenth bonding pad 3P, and the second semiconductor element 21 is connected to the wiring substrate 1 with a flip-chip via a solder 32.

In the third bonding pad 2C, a connection wiring including a plurality of bonding wires is provided from one bonding pad as in the first bonding pad 2A. In the third bonding pad 2C, a slit S3 is provided and a non-connection region regarding the connection wiring of the third bonding pad 2C is partitioned. In one semiconductor device 101, one or more pads selected from a group consisting of a pad including a protrusion (for example, the first bonding pad 2A), a pad in which a region is partitioned in a non-vertical direction with respect to the first direction (not illustrated in FIG. 15), and a pad that is physically partially partitioned (for example, the third bonding pad 2C) may be provided. Since the third bonding pad 2C has an area larger than an area of two bonding pads, the third bonding pad 2C has an advantage from the viewpoint of low resistance, and contributes to durability or/and of reliability the semiconductor device 101.

In the twentieth bonding pad 2D, a connection wiring including a plurality of bonding wires is provided from one bonding pad as in the eleventh bonding pad 2B. In the twentieth bonding pad 2D, a slit S4 is provided and a non-connection region regarding the connection wiring of the twentieth bonding pad 2D is partitioned. In one semiconductor device 101, one or more pads selected from a group consisting of a pad including a protrusion (for example, the eleventh bonding pad 2B), a pad in which a region is partitioned in a non-vertical direction with respect to the first direction (not illustrated in FIG. 15), and a pad that is physically partially partitioned (for example, the twentieth bonding pad 2D) may be provided. Since the twentieth bonding pad 2D has an area larger than an area of two bonding pads, the twentieth bonding pad 2D has an advantage from the viewpoint of low resistance, and contributes to durability or/and reliability of the semiconductor device 101.

A semiconductor element such as the second semiconductor element 21 in the semiconductor device 101 may be a flip-chip.

In a bonding pad in which one bonding pad is connected to one bonding wire, a protrusion may also be provided. By providing a protrusion in such a bonding pad, it is possible to contribute to an improvement in durability or/and reliability of the semiconductor device 101. For example, by providing the seventh bump 5G and the eighth bump 5H in the tenth bonding pad 3H and the nineteenth bonding pad 3P, respectively, it is possible to improve a binding strength of the tenth bonding pad 3H and the nineteenth bonding pad 3P with respect to the encapsulant 8.

### Third Embodiment

A third embodiment relates to a method of manufacturing a semiconductor device, and more specifically relates to a method of manufacturing bonding pads including a protrusion. FIG. 16 is a flowchart illustrating a method of manufacturing a semiconductor device. The method of manufacturing the semiconductor device includes a step of forming a first bonding wire and a second bonding wire in a first bonding pad and a step of forming a protrusion in the first bonding pad. The step of forming the first bonding wire and the second bonding wire in the first bonding pad may be performed first or the step of forming the protrusion in the first bonding pad may be performed first.

By manufacturing a bonding pad including a protrusion by the above steps, it is possible to contribute to an improvement in durability or/and reliability of the semiconductor device 101.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a wiring substrate including a first bonding pad and a second bonding pad aligned with the first bonding pad in a first direction;
a semiconductor element provided on the wiring substrate; and
a connection wiring connecting the first bonding pad to the semiconductor element and including a first bonding wire and a second bonding wire arranged in the first direction, wherein
the first bonding pad includes a region not connected to the connection wiring, the region being partitioned using at least one protrusion provided on a surface of the first bonding pad, the partitioning being in a non-perpendicular direction with respect to the first direction or physically partially partitioned.

2. The semiconductor device according to claim 1, wherein the at least one protrusion includes at least one bump.

3. The semiconductor device according to claim 1, wherein the second bonding pad includes a third bonding wire connected to the semiconductor element.

4. The semiconductor device according to claim 1, wherein a position of the protrusion is displaced in a second direction intersecting the first direction.

5. The semiconductor device according to claim 1, wherein the first bonding pad includes a slit or/and an opening.

6. The semiconductor device according to claim 1, wherein the connection wiring includes a signal wiring or a power wiring.

7. The semiconductor device according to claim 1, wherein the protrusion is connected to the semiconductor element via at least one of the first bonding pad or the connection wiring.

8. The semiconductor device according to claim 1, wherein
a length of the first bonding pad in the first direction is W1,
a length of the first bonding pad in a second direction intersecting the first direction is D1, and
W1 is 0.5 times or more and 5 times or less of D1.

9. The semiconductor device according to claim 1, wherein
a length of the second bonding pad in the first direction is W2,
a length of the second bonding pad in a second direction intersecting the first direction is D2, and
D2 is 1.5 times or more and 15 times or less of W2.

10. The semiconductor device according to claim 1, wherein the protrusion and the first bonding pad include different elements.

11. The semiconductor device according to claim 1, wherein the protrusion is a part of the first bonding pad.

12. The semiconductor device according to claim 1, wherein the protrusion includes a resin.

13. The semiconductor device according to claim 1, wherein the semiconductor element, the first bonding pad, and the second bonding pad are sealed with a mold resin.

14. The semiconductor device according to claim 1, wherein a number of protrusions is equal to or less than a number of bonding wires included in the connection wiring.

15. The semiconductor device according to claim 1, wherein
the protrusion is in contact with a surface layer of the first bonding pad on the surface layer,
the surface layer includes at least of Au, Pd, Ni, or Cu, and
the surface layer is connected to the connection wiring.

16. The semiconductor device according to claim 1, wherein
a center of a first connection region between the first bonding wire and the first bonding pad is a first base point,
a center of a second connection region between the second bonding wire and the first bonding pad is a second base point, and
an angle formed by a Voronoi boundary between the first base point and the second base point along the first direction is equal to or more than 45° and equal to or less than 85°, or equal to or more than 95° or equal to or less than 135°.

17. The semiconductor device according to claim 1, wherein
the connection wiring is located on a semiconductor element side, and
the protrusion is located on a side opposite to the semiconductor element side.

18. The semiconductor device according to claim 1, wherein
a length of the first bonding pad in a second direction intersecting the first direction is D1, and
one or more protrusions are located within a region in a circle that has a diameter substantially equal to ¾ of D1 from a center of the first bonding pad.

19. The semiconductor device according to claim 1, wherein
the first bonding pad includes a slit extending in a second direction intersecting the first direction or/and an opening extending in the second direction,
the slit is opened to a side opposite to a semiconductor element side of the first bonding pad, and
a sum of an area of the slit and an area of the opening is equal to or more than 5% and equal to or less than 30% of an area of the first bonding pad.

20. The semiconductor device according to claim 1, wherein a connection portion of the first bonding wire and the second bonding wire and the first bonding pad has a ball bonding shape or a wedge bonding shape.
